(19) United States
(12) Patent Application Publication
(10) Pub. No.: US 2006/0284241 A1
(43) Pub. Date: Dec. 21, 2006

(54) Nanocrystal non-volatile memory device and method of fabricating the same

(76) Inventor: Il-Gweon Kim, Gyeonggi-do (KR)

Correspondence Address: MYERS BIGEL SIBLEY & SAJOVEC, PO BOX 37428, RALEIGH, NC, 27627, US

(21) Appl. No.: 11/370,086

(22) Filed: Mar. 7, 2006

(30) Foreign Application Priority Data
Jun. 15, 2005 (KR) 10-2005-0051623

(51) Int. Cl. H01L 29/788; H01L 21/336

(52) U.S. Cl. 257/316; 257/321; 438/264; 438/266; 438/594

(57) ABSTRACT

Non-volatile memory cells (e.g., EEPROM cells) utilize floating gate electrodes that are each defined by a plurality of spaced-apart semiconductor nanocrystals. Each of the memory cells includes a semiconductor substrate having a tunnel dielectric layer thereon. A plurality of semiconductor nanocrystals are provided on the tunnel dielectric layer. These plurality of semiconductor nanocrystals operate collectively as a floating gate electrode. Each of the semiconductor nanocrystals is encapsulated in a respective fluorinated dielectric layer. A control dielectric layer is provided on the plurality of semiconductor nanocrystals and an electrically conductive control electrode is provided on the control dielectric layer.

### REFERENCE TO PRIORITY APPLICATION

This application claims the benefit of Korean Patent Application No. 2005-0051623, filed Jun. 15, 2005, the contents of which are hereby incorporated herein by reference in their entirety.

### FIELD OF THE INVENTION

The present invention relates to semiconductor memory devices, and more particularly, to non-volatile memory devices and methods of fabricating the same.

### BACKGROUND OF THE INVENTION

Semiconductor memory devices can be classified into volatile memory devices and non-volatile memory devices according to a manner of storing data. The volatile memory devices lose their stored data when power is not supplied to the volatile memory devices, whereas the non-volatile memory devices maintain their stored data even when power is not supplied to the non-volatile memory devices. Accordingly, non-volatile memory devices having such characteristics (e.g., flash memory devices) are widely used in mobile telecommunication systems, mobile data storage devices, and so forth.

A method of using a floating gate as a storage layer is employed for the non-volatile memory device. A conductor such as polycrystalline silicon is widely used for the floating gate. Accordingly, the floating gate is significantly affected even when small defects are present in a tunnel dielectric, so that a large amount of leakage current occurs.

In recent years, to solve the problem of the non-volatile memory device having the floating gate, research on non-volatile memory devices having nanocrystals have been conducted.

FIG. 1 is a cross-sectional view of a conventional non-volatile memory device having nanocrystals.

Referring to FIG. 1, the conventional nanocrystal non-volatile memory device has an isolation layer 11 which is formed in a predetermined region of a semiconductor substrate 10 and defines an active region 12. Nanocrystals 15 are formed on the active region 12. A control gate electrode 19 is formed on the nanocrystals 15. A tunnel dielectric 13 is interposed between the nanocrystals 15 and the active region 12. A control dielectric 17 is interposed between the nanocrystals 15 and the control gate electrode 19. Source and drain regions 21 and 22 are formed within the active regions 12 at both sides of the control gate electrode 19.

The nanocrystals 15 are composed of semiconductor dots such as silicon. In addition, the nanocrystals 15 are spaced apart from each other. That is, the nanocrystals 15 are insulated from each other by the tunnel dielectric 13 and the control dielectric 17.

The memory device having the nanocrystals 15 can be written by a hot carrier injection mechanism. That is, a write voltage higher than a threshold voltage is applied to the control gate electrode 19, and an electric potential is generated in the source and drain regions 21 and 22. As a result, electrons are injected into the nanocrystals 15. When the electrodes are injected into the nanocrystals 15, the threshold voltage increases. When a read voltage lower than the increased threshold voltage is applied to the control gate electrode 19, no current flows between the source and drain regions 21 and 22, which allows the stored data to be read. In addition, the nanocrystal non-volatile memory devices can be erased by a Fowler-Nordheim (F-N) tunneling mechanism. That is, a negative erase voltage is applied to the control gate electrode 19, and the source and drain regions are grounded or floated, so that the electrons are removed from the nanocrystals 15.

Because the nanocrystals 15 are spaced apart from each other, so that the movement of electrons is restricted between the nanocrystals 15. When the nanocrystals 15 have higher density, a capability of holding the electrons can be enhanced. In addition, when the nanocrystals 15 are smaller, the devices operate at lower voltages. That is, small sizes of the nanocrystals 15 and a large number of the nanocrystals per unit area are required. However, adjacent nanocrystals 15 may be finely connected to form a combined nanocrystal 15B while the nanocrystals 15 are formed as shown in FIG. 1. The combined nanocrystal 15B has a relatively big size.

In addition, the tunnel dielectric 13 may include a local defect. The local defect degrades reliability of the tunnel dielectric 13. In addition, a deformed nanocrystal 15S is formed on the local defect. When this defect is present, electrons injected into the deformed nanocrystals 15S are leaked. A nanocrystal non-volatile memory device is disclosed in U.S. Pat. No. 6,656,792 B2 entitled “Nanocrystal flash memory device and manufacturing method therefor” to Choi et al, and in U.S. Patent Publication No. 2004/0130941A1 entitled “Multibit metal nanocrystal memories and fabrication” to Kan et al.

### SUMMARY OF THE INVENTION

Embodiments of the present invention include integrated circuit memory devices having non-volatile memory cells (e.g., EEPROM cells) therein. These non-volatile memory cells utilize floating gate electrodes that are each defined by a plurality of spaced-apart semiconductor nanocrystals. In particular, embodiments of the present invention include non-volatile memory devices having an array of non-volatile memory cells therein. Each of these memory cells includes a semiconductor substrate having a tunnel dielectric layer thereon. A plurality of semiconductor nanocrystals are provided on the tunnel dielectric layer. These plurality of semiconductor nanocrystals operate collectively as a floating gate electrode of a non-volatile memory cell. Each of the semiconductor nanocrystals is encapsulated in a respective fluorinated dielectric layer. A control dielectric layer is provided on the plurality of semiconductor nanocrystals and an electrically conductive control electrode is provided on the control dielectric layer.

According to further aspects of these embodiments, the tunnel dielectric layer includes a fluorinated tunnel dielectric layer directly on a surface of the semiconductor substrate. The control dielectric layer may also include a fluorinated control dielectric layer contacting a surface of the control electrode. The fluorinated tunnel dielectric layer, the fluorinated control dielectric layer and the fluorinated dielectric layers encapsulating the plurality of semiconductor nanocrystals may be formed of fluorinated silicon dioxide. The control electrode may also include a composite of a polysilicon layer and a tungsten silicide layer.

Still further embodiments of the present invention include methods of forming non-volatile memory devices. These methods include forming a tunnel dielectric layer on a semiconductor substrate and forming a plurality of semiconductor nanocrystals at spaced locations on the tunnel dielectric layer. A control dielectric layer is formed on the plurality of semiconductor nanocrystals and then at least a first one of the plurality of semiconductor nanocrystals is fluorinated to thereby define a fluorinated dielectric layer encapsulating the first one of the plurality of semiconductor nanocrystals. This fluorinating step may include injecting fluorine into the control dielectric layer.

According to further aspects of these embodiments, the step of forming a plurality of semiconductor nanocrystals is preceded by a step of etching-back a surface of the tunnel dielectric layer to increase a degree of roughness of the surface. This etching-back step includes exposing the surface of the tunnel dielectric layer to a solution containing hydrofluoric acid (HF). The step of forming a plurality of semiconductor nanocrystals may include forming a plurality of polysilicon dots on the tunnel dielectric layer. Moreover, the fluorinating step, which may be preceded by a step of forming an electrically conductive control electrode layer on the control dielectric layer, may include injecting fluorine into the control dielectric layer at a dose of greater than about 5×10¹⁵ atoms/cm³. The step of forming a control electrode layer may also include forming a tungsten silicide layer on the control dielectric layer. This step of forming a tungsten silicide layer may include reacting WF₆ with SiH₄ at a temperature in a range from about 300° C. to about 450° C. Alternatively, the step of forming a tungsten silicide layer may include reacting WF₆ with SiH₂Cl₂ at a temperature in a range from about 550° C. to about 650° C. In still further embodiments of the invention, the fluorinating step may include annealing the semiconductor substrate at a temperature of greater than about 750° C.

A nanocrystal non-volatile memory device according to further embodiments of the invention includes a substrate and a tunnel dielectric formed on the substrate. The nanocrystal is formed on the tunnel dielectric. The nanocrystal is surrounded by a fluorinated dielectric. The nanocrystal surrounded by the fluorinated dielectric is covered by a control dielectric. A control gate electrode is formed on the control dielectric. A fluorinated tunnel dielectric may be interposed between the substrate and the tunnel dielectric. In addition, a fluorinated control dielectric may be interposed between the control dielectric and the control gate electrode. The fluorinated dielectric, the fluorinated tunnel dielectric, and the fluorinated control dielectric may be silicon oxide layers containing fluorine (F).

In another embodiment the invention, a method of fabricating a nanocrystal non-volatile memory device is provided. The method includes forming a tunnel dielectric on a substrate. A preliminary nanocrystal is formed on the tunnel dielectric. A control dielectric is formed on the substrate having the preliminary nanocrystal. Fluorine (F) is injected into the substrate having the control dielectric. The preliminary nanocrystal is oxidized to form a fluorinated dielectric. While the fluorinated dielectric is formed, the preliminary nanocrystal is reduced to be a nanocrystal.

The tunnel dielectric may be formed by forming the preliminary tunnel dielectric on the substrate and etching the preliminary tunnel dielectric. In this case, a top surface of the tunnel dielectric may be relatively rough compared to the preliminary tunnel dielectric. Etching the preliminary tunnel dielectric may be carried out using a cleaning solution containing HF acid. The preliminary tunnel dielectric may be formed of an oxide layer such as a silicon oxide layer.

In other embodiments, the preliminary nanocrystal may be composed of semiconductor dots. For example, the preliminary nanocrystal may be composed of polysilicon dots.

In addition, a control gate electrode may be formed on the control dielectric. The control gate electrode may be formed of a polysilicon layer, a metal layer, a metal silicide layer, or a combination layer thereof. The metal silicide layer may be formed of a tungsten silicide (WSi) layer. The WSi layer may be formed by reacting WF₆ with SiH₄ at a temperature of 300° C. to 450° C. Alternatively, the WSi layer may be formed by reacting WF₆ with SiH₂Cl₂ at a temperature of 550° C. to 650° C.

The step of injecting the fluorine may be carried out by an ion injection process after the control gate electrode is formed. Alternatively, the fluorine may be diffused into the substrate while the WSi layer is formed. In addition, after the WSi layer is formed, the ion injection process may be employed to additional inject the fluorine into the substrate. The fluorine may be injected with a dose of 5×10¹⁵ atoms/cm² or more.

Alternatively, the fluorinated dielectric may be formed by annealing the substrate at a temperature of 750° C. or higher. For example, after the control gate electrode is formed, the substrate may be annealed at a temperature of 750° C. or higher to form the fluorinated dielectric. The control gate electrode layer may be patterned to form the control gate electrode. A spacer layer may be formed to conformally cover the substrate. The process of forming the spacer layer may be carried out by inserting the substrate into a reaction chamber heated to a temperature of 750° C. or higher. That is, the fluorinated dielectric may be formed while the spacer layer is formed. While the fluorinated dielectric is formed, a fluorinated tunnel dielectric may be formed between the substrate and the tunnel dielectric. In addition, a fluorinated control dielectric may be formed on the control dielectric.

### BRIEF DESCRIPTION OF THE DRAWINGS

FIG. 1 is a cross-sectional view of a conventional non-volatile memory device having nanocrystals.

FIGS. 2 to 8 are cross-sectional views illustrating methods of fabricating nanocrystal non-volatile memory devices in accordance with exemplary embodiments of the present invention.

FIG. 9 is a characteristic diagram showing a fluorine (F) distribution of the nanocrystal non-volatile memory devices fabricated in accordance with exemplary embodiments of the present invention.

FIG. 10 is a write/erase operating characteristic diagram of the nanocrystal non-volatile memory devices fabricated in accordance with exemplary embodiments of the present invention.

### DETAILED DESCRIPTION OF THE INVENTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. In addition, when a layer is described to be formed on other layer or on a substrate, which means that the layer may be formed on the other layer or on the substrate, or a third layer may be interposed between the layer and the other layer or the substrate. Like numbers refer to like elements throughout the specification.

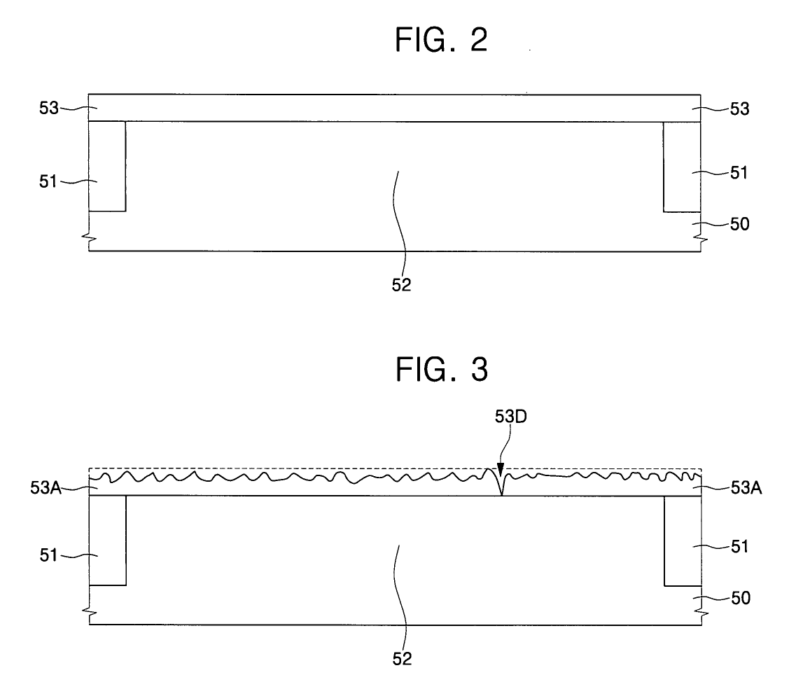

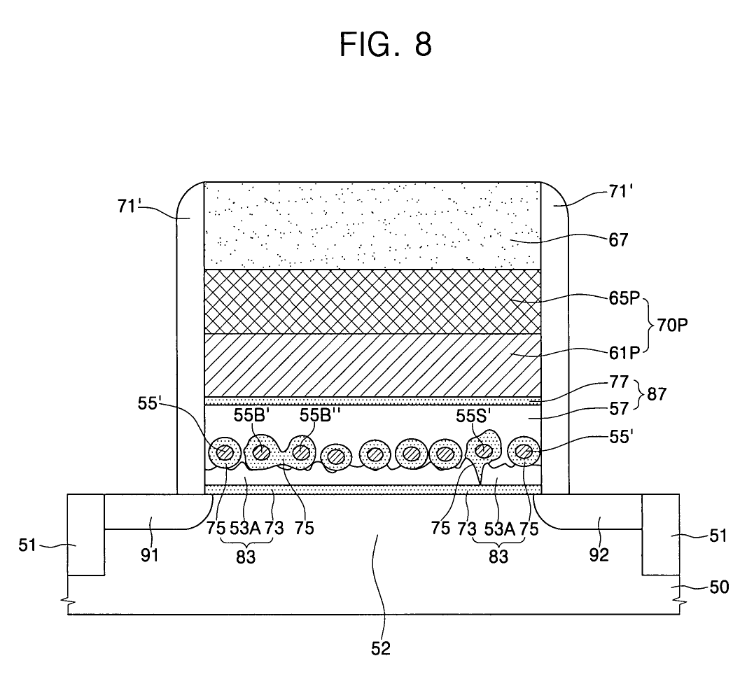

FIGS. 2 to 8 are cross-sectional views illustrating methods of fabricating nanocrystal non-volatile memory devices in accordance with exemplary embodiments of the present invention. First, the nanocrystal non-volatile memory devices according to exemplary embodiments of the present invention will be described with reference to FIG. 8. Referring to FIG. 8, the nanocrystal non-volatile memory device according to exemplary embodiments of the present invention includes a semiconductor substrate 50, a tunnel dielectric 53A, nanocrystals 55′, fluorinated dielectrics 75, a control dielectric 57, and a control gate electrode 70P. The semiconductor substrate 50 may be a substrate such as a silicon wafer. In general, an isolation layer 51, which defines an active region 52, may be formed in the substrate 50. The isolation layer 51 may take the form of a trapezoid of which a top width is larger than a bottom width, however, it is assumed that the top width is the same as the bottom width for simplicity of description.

The tunnel dielectric 53A is disposed on the active region 52. A fluorinated tunnel dielectric 73 may be interposed between the tunnel dielectric 53A and the active region 52. The tunnel dielectric 53A may be an oxide layer such as a silicon oxide layer. The fluorinated tunnel dielectrics 73 may be silicon oxide layers containing fluorine (F). Nanocrystals 55′, 55B′, 55B″, and 55S′ are formed on the tunnel dielectric 53A. Each of the nanocrystals 55′, 55B′, 55B″, and 55S′ is surrounded by the fluorinated dielectric 75. Each of the nanocrystals 55′, 55B′, 55B″, and 55S′ may be a semiconductor dot. For example, each of the nanocrystals 55′, 55B′, 55B″, and 55S′ may be a polysilicon dot. The fluorinated dielectric 75 may be an silicon oxide layer containing F.

The control dielectric 57 is formed on the fluorinated dielectrics 75 and the nanocrystals 55′, 55B′, 55B″, and 55S′. The control dielectric 57 may be an insulating layer such as a silicon oxide layer. The control gate electrode 70P is formed on the control dielectric 57. The control gate electrode 70P may be composed of a polysilicon pattern 61P and a tungsten silicide pattern 65P which are sequentially stacked. In this case, a fluorinated control dielectric 77 may be interposed between the polysilicon pattern 61P and the control dielectric 57. The fluorinated control dielectric 77 may be a silicon oxide layer containing F. Alternatively, the fluorinated control dielectric 77 may not be formed. In addition, the control gate electrode 70P may be a polysilicon pattern 61P, a metal pattern, a metal silicide pattern, or a combination pattern thereof. The metal pattern may be a tungsten (W) pattern. The metal silicide pattern may be the tungsten silicide pattern 65P.

A hard mask pattern 67 may be formed on the control gate electrode 70P. The hard mask pattern 67 may be an insulating layer such as a silicon nitride layer. Side walls of the hard mask pattern 67, the control gate electrode 70P, the control dielectric 57, the nanocrystals 55′, 55B′, 55B″, and 55S′, the fluorinated dielectric 75, and the tunnel dielectric 53A are covered by a spacer 71′. The spacer 71′ may be an insulating layer such as a silicon oxide layer. Source and drain regions 91 and 92 may be disposed within the active region 52 at both sides of the control gate electrode 70P. The fluorinated tunnel dielectric 73, the tunnel dielectric 53A, and the fluorinated dielectric 75 can act as a composite tunnel dielectric 83. The composite tunnel dielectric 83 can have significantly improved insulation properties compared to the related art. In addition, the control dielectric 57 and the fluorinated control dielectric 77 can act as a composite control dielectric 87.

Subsequently, methods of fabricating the nanocrystal non-volatile memory device according to the embodiments of the present invention will be described with reference to FIGS. 2 to 8. Referring to FIG. 2, the methods of fabricating the nanocrystal non-volatile memory device according to the embodiments of the present invention include forming a preliminary tunnel dielectric 53 on a substrate 50. The substrate 50 may be formed of a semiconductor substrate such as a silicon wafer. An isolation layer 51 for defining an active region 52 may be formed on the substrate 50. The isolation layer 51 may be formed of an insulating layer such as a high density plasma (HDP) oxide layer. The isolation layer 51 may take the form of a trapezoid of which a top width is larger than a bottom width, however, it is assumed that the top width is the same as the bottom width for simplicity of description. A preliminary tunnel dielectric 53 may be formed of an oxide layer. For example, the preliminary tunnel dielectric 53 may be formed of a silicon oxide layer having a thickness of 50 Å using a chemical vapor deposition (CVD) method.

Referring to FIG. 3, the preliminary tunnel dielectric 53 is etched to form a tunnel dielectric 53A. The preliminary tunnel dielectric 53 may be etched by a dry etching process and a wet etching process. The wet etching process may be carried out using a cleaning solution containing HF acid. For example, the silicon oxide layer having a thickness of Sum may be etched by a solution containing 1% HF acid so that the tunnel dielectric 53A may be formed to a thickness of 40 Å. As a result, a top surface of the tunnel dielectric 53A may be relatively rough compared to the preliminary tunnel dielectric 53. In addition, while the tunnel dielectric 53A is formed, a local defect 53D may occur in the tunnel dielectric 53A.

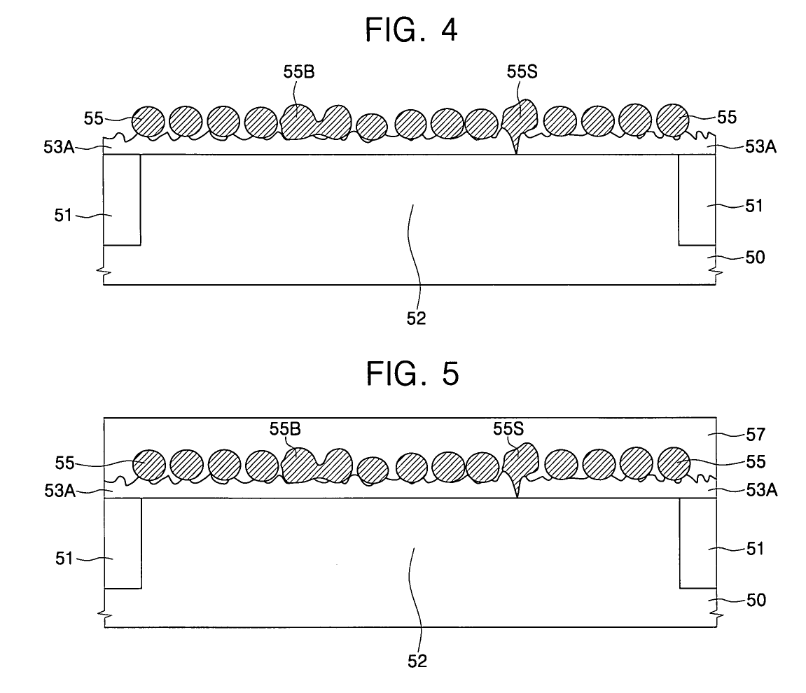

Referring to FIG. 4, preliminary nanocrystals 55, 55B, and 55S are formed on the tunnel dielectric 53A. Preliminary nanocrystals 55 having uniform shapes, combined preliminary nanocrystals 55B, and deformed preliminary nanocrystals 55S may be formed at the same time. The preliminary nanocrystals 55, 55B, and 55S may be formed as semiconductor dots. For example, the preliminary nanocrystals 55, 55B, and 55S may be formed as polysilicon dots. While the preliminary nanocrystals 55, 55B, and 55S are formed, the rough top surface of the tunnel dielectric 53A can act to reduce the sizes of the preliminary nanocrystals 55, 55B, and 55S.

As illustrated, at least two preliminary nanocrystals 55B adjacent to each other may be finely connected to form the combined preliminary nanocrystal 55B. The combined preliminary nanocrystal 55B has a relatively big size. In addition, the deformed preliminary nanocrystal 55S may be formed on the local defect 53D.

Referring to FIG. 5, a control dielectric 57 is formed on the substrate 50 having the preliminary nanocrystals 55, 55B, and 55S. The control dielectric 57 can completely fill spaces between the preliminary nanocrystals 55, 55B, and 55S and cover a top surface of the substrate 50. For example, the control dielectric 57 may be formed of an insulating layer such as a silicon oxide layer having a thickness of 200 Å. As a result, the preliminary nanocrystals 55, 55B, and 55S can be insulated from each other.

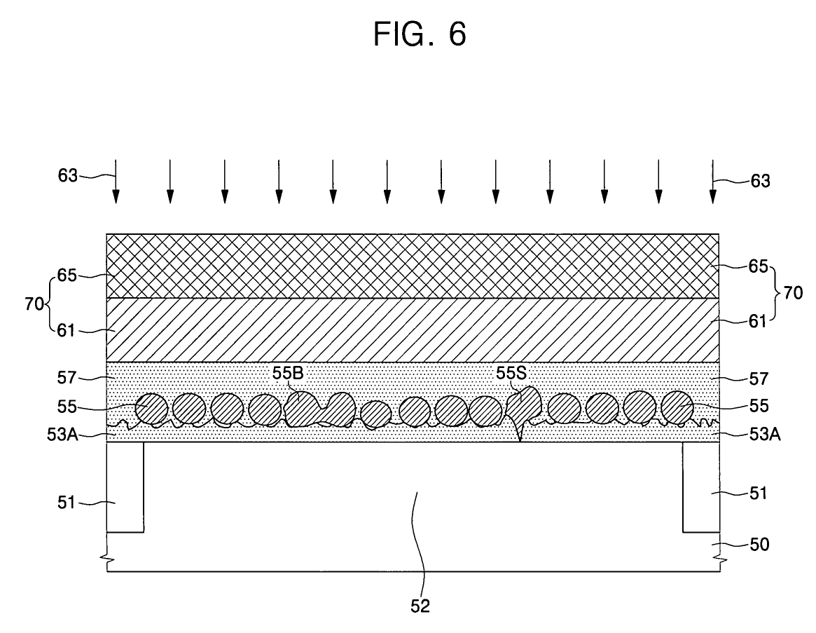

Referring to FIG. 6, a control gate electrode layer 70 may be formed on the substrate 50 having the control dielectric 57. In addition, fluorine is injected into the substrate 50 having the control dielectric 57. The control gate electrode layer 70 may be formed of a polysilicon layer 61, a metal layer, a metal silicide layer, or a combination layer thereof. The metal layer may be formed of a tungsten (W) layer. The metal silicide layer may be formed of a WSi layer 65.

The control gate electrode layer 70 may be composed of the polysilicon layer 61 and the WSi layer 65 which are sequentially stacked. The WSi layer 65 may be formed by reacting WF₆ with SiH₄ at a temperature of 300° C. to 450° C. For example, the WSi layer 65 may be formed using a CVP apparatus at a temperature of 430° C. by Equation (1) below.
2WF₆+7SiH₄→2WSi₂+3SiF₄+14H₂ (1)

Alternatively, The WSi layer 65 may be formed by reacting WF₆ with SiH₂Cl₂ at a temperature of 550° C. to 650° C. For example, the WSi layer 65 may be formed using a CVP apparatus at a temperature of 575° C. by Equation (2) below.
2WF₆+10SiH₂Cl₂→2WSi₂+3SiF₄+8HCl+6H₂ (2)

In Equations 1 and 2, SiF₄, HCI, and H₂ can be formed in a gas state and discharged via a discharge device. In contrast, WSi₂ is deposited on the substrate 50 so that the WSi layer 65 is formed. While the WSi layer 65 is formed, fluorine is diffused into the substrate 50. That is, the fluorine can be injected into the polysilicon layer 61, the control dielectric 57, and the tunnel dielectric 53A. In addition, after the WSi layer 65 is formed, an ion injection process 63 may be employed to additionally inject the fluorine. Alternatively, the additional fluorine injection by the ion injection method 63 may be omitted.

Alternatively, after the control gate electrode layer 70 is formed, only the ion injection method 63 may be employed to inject the fluorine. That is, the fluorine injection into the substrate 50 may be carried out by the ion injection method 63 after the control gate electrode layer 70 is formed. Alternatively, the fluorine injection may be carried out by diffusion of the fluorine while the control gate electrode layer 70 is formed. Alternatively, the fluorine injection may be carried out by both the diffusion and the ion injection method 63. The fluorine injected into the substrate 50 is preferably injected with a dose of 5×10¹⁵ atoms/cm² or more. For example, the fluorine may be injected with a dose of 10¹⁶ atoms/cm² to 10²⁰ atoms/cm².

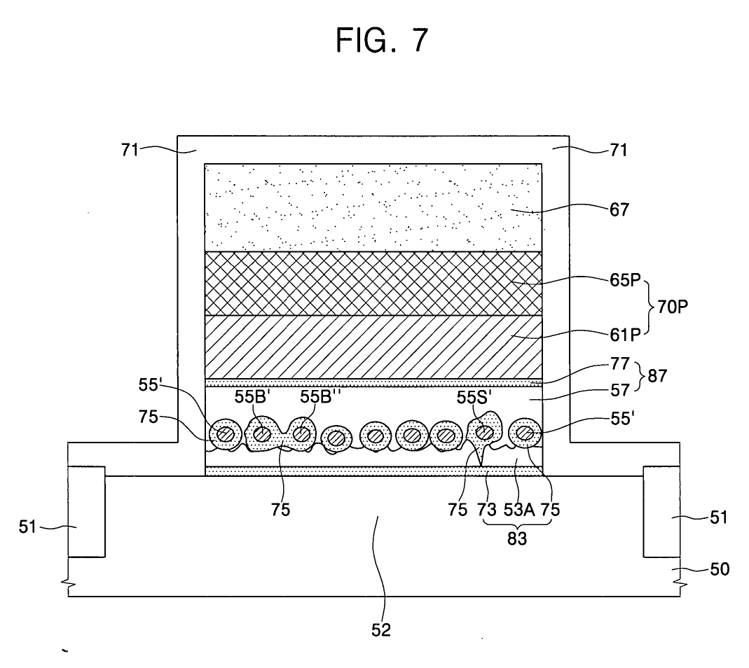

Referring to FIG. 7, the preliminary nanocrystals 55, 55B, and 55S are oxidized to form fluorinated dielectrics 75. While the fluorinated dielectrics 75 are formed, the sizes of the preliminary nanocrystals 55, 55B, and 55S are reduced to form nanocrystals 55′, 55B′, 55B″, and 55S′. That is, the fluorinated dielectrics 75 surround the nanocrystals 55′, 55B′, 55B″, and 55S′. The fluorinated dielectrics 75 may be formed by annealing the substrate 50 having the control gate electrode layer 70. In this case, the fluorinated dielectrics 75 are preferably annealed at a temperature of 750° C. or higher. For example, the substrate 50 having the control gate electrode layer 70 may be annealed at a temperature of 800° C. to form the fluorinated dielectrics 75. At a temperature of 750° C. or higher, the fluorine (F) is high in bonding strength with silicon (Si) compared to oxygen (O). That is, the oxygen (O) can be substituted by the fluorine (F) in the bond of Si—O so that silicon fluoride (Si—F) can be formed. As a result, the oxygen (O) can act to oxidize other surrounding materials.

The tunnel dielectric 53A and the control dielectric 57 may be formed of an oxide layer containing silicon such as a silicon oxide layer. The preliminary nanocrystals 55, 55B, and 55S are formed of semiconductor dots such as polysilicon dots. Accordingly, the silicon oxide layer is dissolved to form silicon fluoride (Si—F), and the oxygen (O) is separated therefrom. The preliminary nanocrystals 55, 55B, and 55S are oxidized by the oxygen (O) to form the fluorinated dielectrics 75. At the same time, the nanocrystals 55′, 55B′, 55B″, and 55S′ remain in the fluorinated dielectrics 75. Consequently, the silicon oxide (Si-0) and the silicon fluoride (Si—F) can be saturated in the fluorinated dielectric 75. That is, the fluorinated dielectrics 75 can be formed of silicon oxide layers containing the fluorine.

While the substrate 50 having the control gate electrode layer 70 is annealed, the combined preliminary nanocrystal 55B may also be processed by the same reaction to form the fluorinated dielectric 75. In this case, finely connected parts between the combined preliminary nanocrystals 55B can be completely transformed to the fluorinated dielectric 75. Accordingly, the combined preliminary nanocrystal 55B can also be oxidized by the oxygen (O) to form the fluorinated dielectric 75, and the nanocrystals 55B′ and 55B″ can be separated in the fluorinated dielectric 75. That is, the separated nanocrystals 55B′ and 55B″ can be insulated from each other by the fluorinated dielectric 75.

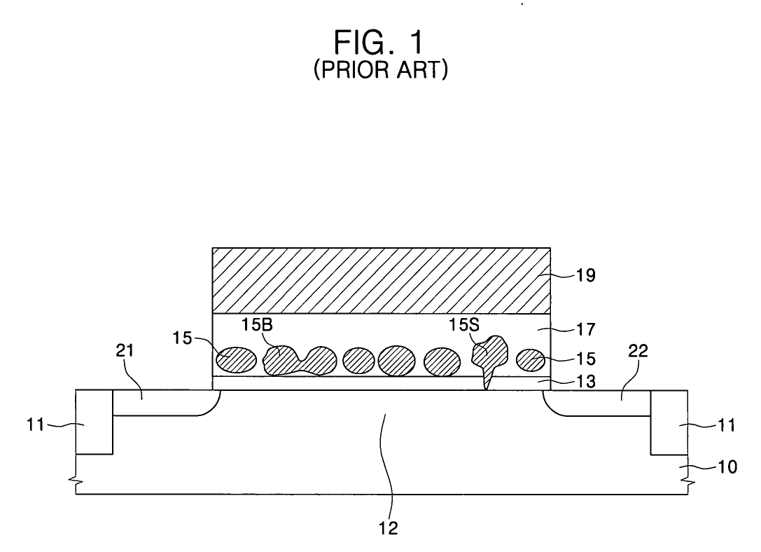

In addition, the deformed preliminary nanocrystal 55S may also be processed by the same reaction to form the fluorinated dielectric 75. In this case, the deformed nanocrystals 55S′ may also be formed in the fluorinated dielectric 75. The deformed preliminary nanocrystal 55S may be a cause of the leakage current which flows via the local defect 53D formed in the tunnel dielectric 53A. In contrast, the deformed nanocrystal 55S′ are surrounded by the fluorinated dielectric 75 so that the leakage current can be prevented. That is, the fluorinated dielectric 75 can act to restore the local defect 53D formed in the tunnel dielectric 53A. Consequently, the nanocrystals 55′, 55B′, 55B″, and 55S′ can be formed which have smaller sizes and larger amounts than the preliminary nanocrystals 55, 55B, and 55S. That is, the nanocrystals 55′, 55B′, 55B″, and 55S′ have smaller sizes and higher densities than the conventional nanocrystals (see, e.g., FIG. 1)

While the substrate 50 having the control gate electrode layer 70 is annealed, the same reaction can be applied between the tunnel dielectric 53A and the active region 52 to form a fluorinated tunnel dielectric 73. In addition, a fluorinated control dielectric 77 can be formed between the control dielectric 57 and the polysilicon layer 61. The fluorinated tunnel dielectric 73, the tunnel dielectric 53A, and the fluorinated dielectric 75 can act as a composite tunnel dielectric 83. The composite tunnel dielectric 83 can have significantly improved insulation compared to the prior art. In addition, the control dielectric 57 and the fluorinated control dielectric 77 can act as a composite control dielectric 87. The fluorinated tunnel dielectric 73 and the fluorinated control dielectric 77 may also be formed of a silicon oxide layer containing fluorine.

The fluorinated dielectrics 75 may be formed by another method. Specifically, the control gate electrode layer 70 may be patterned to form a control gate electrode 70P. The control gate electrode 70P may be formed by forming a hard mask pattern 67 on the control gate electrode layer 70 and etching the control gate electrode layer 70 using the hard mask pattern 67 as an etch mask. The hard mask pattern 67 may be formed of an insulating layer such as a silicon nitride layer. The control gate electrode 70P may be composed of a polysilicon pattern 61P and a tungsten silicide pattern 65P which are sequentially stacked. While the control gate electrode 70P is formed, the control dielectric 57, the preliminary nanocrystals 55, 55B, and 55S, and the tunnel dielectric 53A may be continuously etched to partially expose the active region 52. As a result, the control dielectric 57, the preliminary nanocrystals 55, 55B, and 55S, and the tunnel dielectric 53A can remain below the control gate electrode 70P.

A spacer layer 71 may be formed which conformally covers the substrate 50 having the control gate electrode 70P. The spacer layer 71 may be formed of an insulating layer such as a silicon oxide layer. The process of forming the spacer layer 71 may be carried out by inserting the substrate 50 into a reaction chamber heated to a temperature of 750° C. or higher. For example, the spacer layer 71 may be formed at a temperature of 800° C. by means of a CVD apparatus. While the spacer layer 71 is formed, the preliminary nanocrystals 55, 55B, and 55S may be oxidized to form the fluorinated dielectrics 75. At the same time, the nanocrystals 55′, 55B′, 55B″, and 55S′ can remain in the fluorinated dielectrics 75. While the fluorinated dielectrics 75 are formed, the fluorinated tunnel dielectric 73 may be formed between the substrate 50 and the tunnel dielectric 53A. In addition, a fluorinated control dielectric 77 may be formed on the control dielectric 57.

Referring to FIG. 8, the spacer layer 71 may be anisotropically etched to form a spacer 71′. As a result, sidewalls of the hard mask pattern 67, the control gate electrode 70P, the control dielectric 57, the nanocrystals 55′, 55B′, 55B″, 55S′, the fluorinated dielectric 75, and the tunnel dielectric 53A can be covered by the spacer 71′. A typical process of fabricating a semiconductor device such as formation of source and drain regions 91 and 92 within the active region 52 at both sides of the control gate electrode 70P, may be then employed to fabricate the non-volatile memory device.

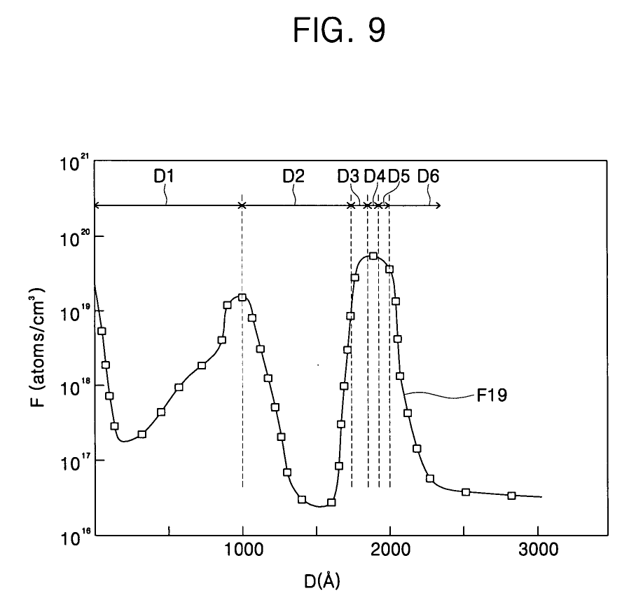

FIG. 9 is a characteristic diagram showing a fluorine distribution of the nanocrystal non-volatile memory device fabricated in accordance with exemplary embodiments of the present invention. A fabrication history of the device will be first described. A tunnel dielectric having a thickness of 50 Å is formed on a silicon wafer. The tunnel dielectric is formed of a silicon oxide layer. A surface of the tunnel dielectric is etched using a solution containing 1% HF acid. As a result, the tunnel dielectric is removed by about 10 Å to have a thickness of 40 Å. A process of forming polysilicon on the tunnel dielectric is employed to form preliminary nanocrystals. A control dielectric having a thickness of 200 Å is formed on the silicon wafer having the preliminary nanocrystals. The control dielectric is also formed of a silicon oxide layer. A polysilicon layer is formed on the control dielectric. A tungsten silicide (WSi) layer having a thickness of 1000 Å is formed on the polysilicon layer. The WSi layer may be formed by reacting WF₆ with SiH₄ at a temperature of 430° C. The silicon wafer having the WSi layer is annealed for 30 minutes at a temperature of 800° C. to form fluorinated dielectrics and nanocrystals. FIG. 9 shows the result which has analyzed the concentration of the fluorine in the device using energy dispersive X-ray (EDX). A horizontal axis of FIG. 9 indicates a surface depth of the device, and its unit is Angstrom (□). A vertical axis of FIG. 9 indicates the concentration of the fluorine, and its unit is atoms/cm³.

Referring to FIG. 9, a curve F19 indicates the characteristic of the concentration of the fluorine per surface depth of the device. A first interval D1 corresponds to the WSi layer, a second interval D2 corresponds to the polysilicon layer, a third interval D3 corresponds to the control dielectric, a fourth interval D4 corresponds to the nanocrystals, a fifth interval D5 corresponds to the tunnel dielectric, and a sixth interval D6 corresponds to the silicon wafer. Referring to the third to fifth intervals D3, D4, D5 of the curve F19, it can be seen that the fluorine having a concentration of 10¹⁹ atoms/cm³ is distributed between the tunnel dielectric and the control dielectric. That is, it can be seen that the fluorine can be injected by the process of forming the WSi layer.

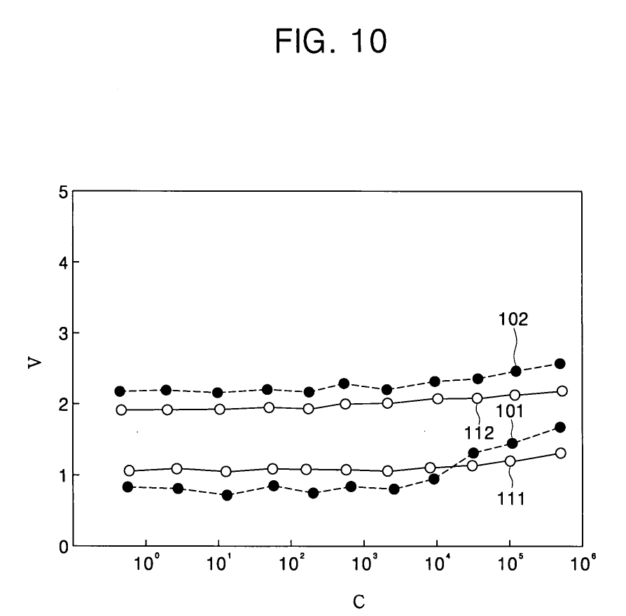

FIG. 10 is an operating characteristic diagram showing repeated test results of write and erase operations of the nanocrystal non-volatile memory devices fabricated in accordance with embodiments of the present invention. A horizontal axis (C) in FIG. 10 indicates the number of repeated write and erase tests of the device, and its unit is the number of times. A vertical axis (V) in FIG. 10 indicates a threshold voltage (Vth), and its unit is volts. Referring to FIG. 10, a curve 111 corresponds to an erase characteristic curve of the nanocrystal non-volatile memory device where the fluorine is injected with a dose of 3×10¹⁷ atoms/cm², a curve 112 corresponds to a write characteristic curve of the nanocrystal non-volatile memory device where the fluorine is injected with a dose of 3×10¹⁷ atoms/cm². In addition, a curve 101 corresponds to an erase characteristic curve of the nanocrystal non-volatile memory device where the fluorine is injected with a dose of 9×10¹⁴ atoms/cm², and a curve 102 corresponds to a write characteristic curve of the nanocrystal non-volatile memory device where the fluorine is injected with a dose of 9×10¹⁴ atoms/cm². All of these nanocrystal non-volatile memory devices were fabricated to W=10 μm and L=0.2 μm.

The nanocrystal non-volatile memory devices can be written by a hot carrier injection mechanism. That is, a write voltage of 5V is applied to the control gate electrode, and an electric potential of 4V occurs between source and drain. In addition, the nanocrystal non-volatile memory devices can be erased by a Fowler-Nordheim (F—N) tunneling mechanism. That is, an erase voltage of −8V is applied to the control gate electrode and 0V is applied to the source and drain.

As shown in FIG. 10, it can be seen that the threshold voltage increases after the repeated tests of 10⁴ in the case of the curve 101. The increase in the threshold voltage means an incomplete erase. In contrast, it can be seen that the change of the threshold voltage is relatively insignificant even after the repeated tests of 10⁵ in the case of the curve 111. That is, the nanocrystal non-volatile memory device fabricated by injecting the fluorine with a dose of 5×10¹⁵ atoms/cm² or more in accordance with the embodiments of the present invention shows relatively superior write and erase characteristics.

According to the present invention as described above, a preliminary nanocrystal is formed on a tunnel dielectric, and a control dielectric is formed on the preliminary nanocrystal. Fluorine (F) is injected into the substrate having the control dielectric. The preliminary nanocrystal is oxidized to form a fluorinated dielectric. While the fluorinated dielectric is formed, the size of the preliminary nanocrystal is reduced to form a nanocrystal. Accordingly, the non-volatile memory device having nanocrystals of smaller size and high density can be fabricated. While the fluorinated dielectric is formed, a fluorinated tunnel dielectric may be formed between the substrate and the tunnel dielectric. The fluorinated tunnel dielectric, the tunnel dielectric, and the fluorinated dielectric can act as a composite tunnel dielectric. The composite tunnel dielectric has superior insulation relative to the prior art. That is, the composite tunnel dielectric has good reliability. Consequently, the nanocrystal non-volatile having lower power consumption and higher reliability can be implemented.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A non-volatile memory cell, comprising:
a semiconductor substrate having a tunnel dielectric layer thereon;
a plurality of semiconductor nanocrystals encapsulated in respective fluorinated dielectric layers, on the tunnel dielectric layer;
a control dielectric layer on said plurality of semiconductor nanocrystals; and
a control electrode on said control dielectric layer.

2. The non-volatile memory cell of claim 1, wherein the tunnel dielectric layer comprises a fluorinated tunnel dielectric layer directly on a surface of said semiconductor substrate.

3. The non-volatile memory cell of claim 2, wherein said control dielectric layer comprises a fluorinated control dielectric layer contacting a surface of said control electrode.

4. The non-volatile memory cell of claim 3, wherein the fluorinated tunnel dielectric layer, the fluorinated control dielectric layer and the fluorinated dielectric layers encapsulating said plurality of semiconductor nanocrystals comprise fluorinated silicon dioxide.

5. The non-volatile memory cell of claim 1, wherein said control dielectric layer comprises a fluorinated control dielectric layer contacting a surface of said control electrode.

6. The non-volatile memory cell of claim 1, wherein said control electrode comprises a composite of a polysilicon layer and a tungsten silicide layer.

7. A method of forming a non-volatile memory device, comprising the steps of:
forming a tunnel dielectric layer on a semiconductor substrate;
forming a plurality of semiconductor nanocrystals at spaced locations on the tunnel dielectric layer;
forming a control dielectric layer on the plurality of semiconductor nanocrystals; and then
fluorinating at least a first one of the plurality of semiconductor nanocrystals to define a fluorinated dielectric layer encapsulating the first one of the plurality of semiconductor nanocrystals.

8. The method of claim 7, wherein said fluorinating step comprises injecting fluorine into the control dielectric layer.

9. The method of claim 8, wherein said step of forming a plurality of semiconductor nanocrystals is preceded by a step of etching-back a surface of the tunnel dielectric layer to increase a degree of roughness of the surface.

10. The method of claim 9, wherein said etching-back step comprises exposing the surface of the tunnel dielectric layer to a solution containing hydrofluoric acid (HF).

11. The method of claim 7, wherein said step of forming a plurality of semiconductor nanocrystals comprises forming a plurality of polysilicon dots on the tunnel dielectric layer.

12. The method of claim 7, wherein said fluorinating step comprises injecting fluorine into the control dielectric layer at a dose of greater than about 5×10¹⁵ atoms/cm³.

13. The method of claim 7, wherein said fluorinating step is preceded by a step of forming an electrically conductive control electrode layer on the control dielectric layer.

14. The method of claim 13, wherein said fluorinating step comprises injecting fluorine into the control electrode layer.

15. The method of claim 13, wherein forming a control electrode layer comprise forming a tungsten silicide layer on the control dielectric layer.

16. The method of claim 15, wherein forming a tungsten silicide layer comprises reacting WF₆ with SiH₄ at a temperature in a range from about 300° C. to about 450° C.

17. The method of claim 15, wherein forming a tungsten silicide layer comprises reacting WF₆ with SiH₂Cl₂ at a temperature in a range from about 550° C. to about 650° C.

18. The method of claim 7, wherein said fluorinating step is performing concurrently with forming a control electrode layer on the control dielectric layer.

19. The method of claim 7, wherein said fluorinating step comprises annealing the semiconductor substrate at a temperature of greater than about 750° C.

20.-51. (canceled)
